(19) United States
(12) Patent Application Publication
(10) Pub. No.: US 2011/0284062 A1
(43) Pub. Date: Nov. 24, 2011

(54) METHOD FOR THE DEPOSITION OF MICROCRYSTALLINE SILICON ON A SUBSTRATE

(76) Inventors: Aad Gordijn, Juelich (DE); Thilo Kilper, Oldenburg (DE); Bernd Rech, Berlin (DE); Sandra Schicho, Sherbrooke (CA)

(21) Appl. No.: 12/998,821

(22) PCT Filed: Nov. 18, 2009
(86) PCT No.: PCT/DE2009/001649

§ 371 Date: Aug. 5, 2011

(30) Foreign Application Priority Data
Dec. 18, 2008 (DE) 10 2008 063 737.8

(51) Int. Cl. H01L 21/20; H01L 31/0384

(52) U.S. Cl. 136/255; 438/488; 257/E21.09

(57) ABSTRACT

Disclosed is a method for depositing microcrystalline silicon on a substrate in a plasma chamber system, comprising the following steps: prior to initiating the plasma, providing the plasma chamber system with at least one reactive, silicon-containing gas and hydrogen, or exclusively hydrogen; initiating the plasma; after the plasma is initiated, continuously supplying the chamber system exclusively with reactive, silicon-containing gas, or after the plasma is initiated, continuously supplying the chamber system with at least one mixture comprising a reactive, silicon-containing gas and hydrogen, wherein the concentration of reactive, silicon-containing gas during the supply into the chamber is adjusted to greater than 0.5%; adjusting the plasma power to between 0.1 and 2.5 W/cm² electrode surface; selecting a deposition rate of greater than 0.5 nm/s; and depositing, the microcrystalline layer having a thickness of less than 1000 nanometers on the substrate.

The invention relates to a method for depositing microcrystalline silicon on a substrate.

Microcrystalline silicon (μc-Si:H) is a material that is notably used in solar cells as an absorber material. It is produced today in many laboratories from silicon-containing gas (typically silane) and hydrogen using the PECVD (plasma-enhanced chemical vapor deposition) method.

When employing different deposition regimens, it is possible to deposit high-quality layers made of microcrystalline silicon. In the PECVD method, the silane-hydrogen mixture is generally introduced to the plasma chamber and a corresponding amount of gas is pumped out, while at the same time a plasma burns in the plasma chamber, which causes the dissociation of silane and hydrogen molecules, and hence the generation of precursor products for the microcrystalline silicon layer that is added by epitaxial growth. In deposition using PECVD at the standard industry frequency of 13.56 MHz, the silane concentration (=silane flow/(sum of silane flow and hydrogen flow)) is typically approximately 1%, and at excitation frequencies in the VHF range it is generally less than 10%. The hydrogen is required to influence layer growth. However, only a small part of the hydrogen that is used is incorporated in the silicon layer that is produced, typically less than 10%. The remaining hydrogen is pumped off.

Methods for depositing microcrystalline silicon by means of PECVD are known from the prior art, in which hydrogen consumption, which constitutes one factor in the manufacturing cost of solar cells, can be reduced.

1. The “closed-chamber CVD” (CC-CVD) method. This process, which was explored, runs cyclically (discontinuously) and comprises substantially two process steps. In a first step, a small amount of the reactive process gas (silicon-containing gas, for example SiH₄ or a CH₄/SiH₄ mixture) flows through the chamber at a ratio of approximately 25% reactive gas to hydrogen. This step is intended to refresh the gas atmosphere after a process cycle. During this time, the plasma burns at low power (approximately 10 W), so that an ultrathin silicon layer is deposited. In the subsequent second step, both pumping out of the chamber and the gas supply into the chamber are interrupted. Delaying the shut-off of the hydrogen supply increases the deposition pressure and lowers the silane concentration to ˜5%. The plasma then continues to burn at approximately 60 W. The process gases are gradually decomposed, and the deposited layer continues to grow. At the same time, a contrary effect takes place. The layer is etched by H-radicals. Due to the rising hydrogen component in the plasma, the etching rate continues to increase, until a balance is ultimately reached between layer growth and etching. Atoms that are weakly bound are preferentially etched, so that ultimately a network having stronger bonds is formed. The entire deposition process takes place as a continuous succession of these two steps (layer by layer) up to the desired layer thickness. A crystalline volume fraction of more than 90% has been reported. However, due to the cyclical changes in the process conditions, this process is very complex. It differs fundamentally from the standard PECVD method that is used, and so far it is not yet suited for industrial use. In addition, it has not yet been possible to produce any solar cells with this method.

2. The “static closed chamber” (VHFGD) method. This “very high frequency glow discharge” (VHFGD) deposition method is a continuous process in which no hydrogen whatsoever is used. The deposition chamber (plasma chamber) is not fully insulated. A low silane flow is introduced to the chamber and, at the same time, a corresponding amount of gas is pumped out. The deposition takes place with VHF excitation at low pressure (0.1 mbar). Hydrogen is released during the deposition of silicon from silane. The low silane gas flow ensures silane depletion. The initially fast deposition of the silicon is slowed by the increase in dissociated hydrogen. After approximately one minute, static conditions exist, with a low ratio of [SiH*]/[Hα], which allows for continuous microcrystalline growth. Because the deposition is started with pure silane plasma, and hydrogen is not added until later by the decomposition of the silane, the deposited layer comprises a pronounced amorphous incubation layer (˜0.1 nm) as the first layer. This can result in a considerable impairment of the function when such layers are used in building components, particularly in solar cells. For example, an efficiency of only 2.5% was achieved with solar cells in which the absorber layer was produced using this method.

3. A method for depositing microcrystalline silicon for the absorber layer is known from DE 103 08 381 A1, which also has low hydrogen consumption. For this purpose, the process starts with a large amount of hydrogen, and the hydrogen supply is drastically lowered after the plasma is initiated. However, as differs from methods 1 and 2, this method allows considerably higher solar cell efficiencies, of up to 7%, to be achieved.

For a method for producing solar cells to be able to be used industrially, in addition to hydrogen consumption, the quantities that are produced per unit of time are an important criterion. For a predefined deposition rate in nm/s, the thickness of the solar cell is therefore a criterion.

It is known from Vetterl et al. (O. Vetterl, A. Lambertz, A. Dasgupta, F. Finger, B. Rech, O. Kluth, H. Wagner (2006). Thickness dependence of microcrystalline silicon solar cell properties. Solar Energy Materials & Solar Cells. 66, 345-351) that with layer thicknesses of <1 μM for the μc-Si:H absorber layer (i-layer), the achievable efficiency η of μc-Si:H single solar cells as the product of the open-circuit voltage (V_{OC}), short-circuit current density (J_{SC}) and fill factor (FF) considerably decreases. Thus, in practical experience, for the μc-Si:H absorber layer, a layer thickness of >1 μm, has been established for an optimized solar cell. In this way, single solar cells having an efficiency of greater than or equal to 8% are provided when using a ZnO/AG as the back contact. The back contact denotes the side facing away from the light. The front denotes the side facing the light.

It is known from Rath (J. K. Rath (2003). Low temperature polycrystalline silicon: a review on deposition, physical properties and solar cell applications. Solar Energy Materials & Solar Cells 76, 431-487) that the ‘deposition rate’ parameter of the μc-Si:H absorber layer likewise negatively influences the ‘efficiency’ parameter of what will later be the cell. The higher the deposition rate that is selected for the absorber layer, the lower the cell efficiency that can be achieved. Raising the deposition rate for the μc-Si:H absorber layer, for example by increasing the plasma power to over 0.3 W/cm² electrode surface, therefore has a disadvantage, at a plasma excitation frequency of 13.56 MHz, in the achievable cell efficiency is already considerably reduced for μc-Si:H single solar cells having standard layer thicknesses of approximately 1000 to 2000 nanometers. The same thus applies to multi-junction solar cells that comprise such μc-Si:H absorber layers.

It is the object of the invention to provide a fast method for depositing microcrystalline silicon on a substrate, which nonetheless leads to high solar cell efficiencies.

The object is achieved by a method according to claim 1. Advantageous embodiments will be apparent from the dependent claims.

The method for depositing microcrystalline silicon on a substrate in a plasma chamber system comprises the following steps:
prior to initiating the plasma, providing the plasma chamber system with a reactive, silicon-containing gas and hydrogen, or exclusively hydrogen;
initiating the plasma;
after the plasma is initiated, continuously supplying exclusively reactive, silicon-containing gas to the chamber system or, after the plasma is initiated, continuously supplying a mixture comprising a reactive, silicon-containing gas and hydrogen to the chamber system, wherein the concentration of reactive, silicon-containing gas during the supply into the chamber is adjusted to greater than 0.5%;
adjusting the plasma power to between 0.1 and 2.5 W/cm² electrode surface; and
selecting a deposition rate greater than 0.5 nm/sand depositing a microcrystalline layer on the substrate that does not exceed a thickness of 1000 nm.

The silane concentration (=silane flow/(sum of silane flow and hydrogen flow)) is adjusted so that the deposition of the microcrystalline absorber layer takes place close to the μc-Si:H/a-Si:H growth junction. The reason for this is that optimal absorber layer properties are not achieved by a high crystalline component, but rather materials in the junction region having amorphous and crystalline components exhibit the best properties. The reason for these favorable properties is considered to be optimal interface passivation of the silicon crystallites by amorphous silicon.

In depositing the microcrystalline layer, it is possible to admix inert gases, for example argon, to the process gases (silicon-containing gas and hydrogen) prior to and/or after the plasma is initiated.

With otherwise identical process parameters, increasing the generator power results in a higher crystalline volume component of the layer that is grown.

The method according to the invention advantageously comprises the characteristics that are particularly advantageous for a mass production of solar cells on an industrial scale. This is the deposition of a comparatively thin μc-Si:H absorber layer together with a high deposition rate. It is unimportant whether the microcrystalline absorber layer is deposited for a single cell or for a multi-junction solar cell. The measure of raising the deposition rate with thin microcrystalline absorber layers, by itself achieves the object of the invention, regardless of the substrate that is selected and the related design of the solar cell0

The term ‘plasma chamber system’ encompasses all common plasma chambers for the deposition of solar cells. The method can thus generally be applied to both single chambers and to combined plasma chamber systems comprising a plurality of single chambers.

The plasma chamber system can, for example, comprise an single chamber for producing intrinsic a-Si:H and μc-Si:H absorber layers (i-chamber), a further single chamber for producing p- or n-doped a-Si:H and μc-Si:H layers (doping chamber), and a charging chamber for inwardly and outwardly transferring substrates.

Within the context of the invention, it was found that, when raising the deposition rate to more than 0.5 nm/s and simultaneously using thin μc-Si:H absorber layers having a layer thickness of less than 1000 nm, no further noteworthy loss of efficiency takes place based on an increase in the deposition rate. Any combination of intermediate values for the deposition rate and the layer thickness are allowed. In contrast, with the thick microcrystalline absorber layers preferred according to the prior art until now, having layer thicknesses of more than 1000 nm, increasing the deposition rate, for example from 1 to 2.5 nm/s, leads to a considerable loss in efficiency.

The deposition rate can be selected at up to 5 nm/s, depending on the plasma power or generator power.

To produce p- or n-doped silicon layers in the doping chamber, it is possible to further admix a boron-containing (for example, trimethyl boron B(CH₃)₃) or phosphorus-containing (for example, phosphine PH₃) gas to the process gas mixture composed of silicon-containing gas and H₂. To avoid doping agent carry-overs during the production of intrinsic silicon absorber layers to as great an extent as possible, the i-chamber and the doping chamber are preferably separated from each other by a gate.

The i-chamber can contain one or more different high-frequency electrodes, which can have a “showerhead” design for homogeneous gas injection, the electrode surfaces of which can be oriented vertically or horizontally. The substrate to be coated can be moved to the electrode on which the −silicon deposition is to take place using a transport system. Once the substrate has assumed the final position, a heater system ensures that the substrate is heated to the desired substrate temperature prior to starting deposition. The distance between the high-frequency electrode and the substrate can be adjusted, for example, to values between 5 and 25 mm.

The term ‘deposition rate’ is defined here as the thickness of the deposited absorber layer per unit of time. The deposition rate, in general, rises with increasing plasma power or generator power.

A plasma excitation frequency of 13.56 to approximately 100 MHz can preferably be selected, with an electrode distance of 5 to 25 millimeters, and preferably 10 to 25 millimeters.

The deposition pressure in the plasma chamber is preferably adjusted, during the method, to between 1 and 25 mbar, in the plasma chamber or in the plasma chambers. With otherwise identical process parameters, increasing the deposition pressures results in a lower crystalline volume component of the layer that is grown.

In a further particularly advantageous embodiment of the invention, the method can be designed so that the base pressure in the plasma chamber system is at least 10⁻⁶ mbar or even greater, which is to say, for example 10⁻⁵ mbar or 10⁻⁴ mbar. Any intermediate value is possible.

The base pressure is the prevailing pressure in the plasma chamber, or in the plasma chamber system, in the evacuated state before introducing the process gases, and is dependent on, amongst other things, the design of the chamber and the purity of the gases that are used.

According to the prior art, the plasma chamber, or the plasma chamber system, of a small laboratory facility has a base pressure of approximately 10⁻⁸ mbar. This is due to the high purity levels addressed above, at which the methods according to the prior art must be operated to achieve the desired high solar cell efficiencies. It has become widely accepted that the oxygen content in μc-Si:H absorber layers should not exceed a certain threshold under any circumstances, because otherwise the efficiency that can be achieved both by μc-Si:H-based single solar cells and a-Si:H/μc-Si:H-based multi-junction solar cells is subject to considerable and undesirable loss. Therefore, with respect to process purity, the prior art necessitated that the oxygen content in the μcc-Si:H absorber layer always remained below an allowed threshold, in order to achieve high cell efficiencies. According to the prior art, this threshold is approximately 2*10¹⁹/cm³ oxygen atoms for the μc-Si:H absorber layer, and standard layer thicknesses of >1000 nm for the μc:Si:H absorber layer. The process purity level was associated with high facility costs because of the pump systems that had to be used. The operating costs per se are likewise comparatively high, because the purity level of the process gases, which are essentially silane, or silicon-containing gas in general, and hydrogen, also had to be selected at high levels.

It was found, within the context of the invention, that particularly advantageously a synergistic effect occurs at high deposition rates of greater than 0.5 nm/s and, at the same time, with low layer thicknesses of less than 1000 nm for the deposited microcrystalline absorber layer, so that despite a very high base pressure of 10⁻⁵ mbar or more, and up to 10⁻⁶ mbar, only a small loss of cell efficiency occurs, which is absolutely acceptable from a process-related point of view. With respect to these three parameters of a deposition rate >0.5 nm/s, a layer thickness <1000 nm and a base pressure >10⁻⁶ mbar, here again, any intermediate value can be assumed for the method.

It was found that, compared to low deposition rates, high deposition rates according to the invention cause lower oxygen quantities to be incorporated in the μc-Si:H layer that is grown at the same base pressure. It was further found that the acceptable oxygen content in single solar cells, up to which no losses of efficiency occur, is higher with thin absorber layers than with thick absorber layers. The same applies in turn to all forms of multi-junction solar cells.

The consequence of the discoveries described above, which is to say the influence of the deposition rate and/or of the oxygen content on the achievable μc-Si:H single solar cell efficiency as a function of the absorber layer thickness, is that the production-cost optimum for thin-film solar modules containing μc-Si:H absorber layers shifts toward considerably lower overall layer thicknesses. This also applies to multi-junction solar cells.

It was found that, within the context of the method according to the invention, the achievable cell efficiency may then slightly decrease; however, in addition to the shorter manufacturing time, this disadvantage is more than compensated for by the reduced layer thickness, and potentially less stringent requirements in terms of the purity of the process (the gases) and the cells that are produced, in terms of the oxygen content, and in so much as, in this case, the solar cell manufacturing time can be even further shortened by a significant amount, due to the increase in the deposition rate of the μc-Si:H absorber layer, without additional efficiency losses. Production can thus be carried out with considerably less stringent requirements in terms of the purity of the process, which entails significant cost advantages, and more specifically lower equipment costs and lower process gas costs. Consideration must also be given to the fact that thinner a-Si:H/μc-Si:H-based multi-junction solar cells degrade less. As a result the difference in terms of the stabilized efficiency as compared to the starting efficiency, is less than that in the case of a-Si:H/μc-Si:H-based multi-junction solar cells having a standard overall layer thickness.

In a further embodiment of the invention, the method can be carried out so that the flows of the gases, or gas mixtures, supplied to the chamber and discharged from the chamber are controlled so that a constant deposition pressure develops during the process.

Notably a deposition rate of approximately 1.0 to 2.5 nm/s can be selected, and a microcrystalline layer having a thickness of 200 to 800 nm, and more particularly of 400 to 600 nm, can be deposited. In these cases, the described method can generally be used to implement μc-Si:H single solar cells having an efficiency of approximately 7 to 8%, likewise for any combination of intermediate values. For a-Si:H/μc-Si:H-based multi-junction solar cells, which due to the a-Si:H component initially suffer light induced degradation, and only then exhibit stabilized efficiency, higher starting efficiencies of approximately 9 to 11%, and also higher stabilized efficiencies of approximately 8 to 10%, can be achieved without difficulty.

After the plasma is initiated, the chamber can be continuously supplied exclusively with reactive, silicon-containing gas at a volume flow of 0.5 sccm to 20 sccm/100 cm² coating surface, and more particularly of 0.5 sccm to 10 sccm/100 cm² coating surface. This applies, for example, when the chamber, or the chamber system, comprises hydrogen without silicon-containing gas prior to the beginning of the plasma initiation. At the same time, the gas mixture present in the chamber can be discharged at least partially from the chamber. It is possible to admix inert gases in this method.

The method for depositing the microcrystalline silicon can notably be used to produce multi-junction solar cells. In the method, an electrical contact layer and a microcrystalline n-layer deposited thereon are then selected as the substrate, for example. In the case of the tandem configuration, the solar cell has an n-i-p-n-i-p configuration in the finished state. The electrical contact layer that is selected can be, for example, a metal-ZnO layer, or a metal-SnO₂ layer, or another TCO layer. It is also possible to contact only a metal layer as a reflector as the electrical contact layer of the n-i-p-n-i-p layer. Single cells are produced without the corresponding a-Si:H component.

The substrate can also be selected, for example, to be a glass-TCO-a-Si:H layer system, with a microcrystalline p-layer deposited thereon. It is also possible to select a metal-TCO-a-Si:H layer system, with a microcrystalline p-layer deposited thereon. In these cases of a tandem configuration, the solar cell has an p-i-n-p-i-n configuration in the finished state. Substrates without the corresponding a-Si:H component are selected for single cells. Of course it is possible to use other substrates for producing the multi junction solar cells.

The solar cells produced by means of this method thus have at least one n-i-p structure or a p-i-n structure, wherein the absorber layer has a microcrystalline design. For example, μc-Si:H single solar cells produced by the method according to the invention at a particularly advantageous deposition rate of 2.5 nm/s have an efficiency of approximately 7 to 8%. They are characterized in that the μc-Si:H absorber layer has a thickness of less than 1000 nanometers.

It is particularly advantageous if the single solar cells produced by the method according to the invention have an efficiency of 7 to 8%, despite high deposition rates and low layer thicknesses. With multi-junction solar cells, accordingly higher efficiencies can be achieved.

In a particularly advantageous embodiment of the invention, the solar cells produced by means of this method may comprise more than 2*10¹⁹, and up to approximately 1*10²¹ cm⁻³, of oxygen atoms in the microcrystalline absorber layer.

An a-Si:H/μc-Si:H-based multi-junction solar cell particularly advantageously has an overall layer thickness, of all absorber layers, of less than 1000 nanometers. In consideration of the manufacturing costs per watt of peak nominal solar module power, the microcrystalline absorber layer preferably has an oxygen content of more than 2*10¹⁹, and notably up to 10²¹ oxygen atoms/cm³.

With the method, it is particularly advantageously possible to produce thin a-Si:H/μc-Si:H multi-junction solar cells, and in particular tandem solar cells, wherein the usual negative effects of a high deposition rate for the μc-Si:H absorber layer and of a high concentration of impurities in the μc-Si:H absorber layer are considerably less pronounced. In this way, additional cost savings become possible by a further reduction in manufacturing times and less stringent requirements in terms of the purity of the process. Here, a synergistic effect also takes place because, compared to lower deposition rates, high deposition rates cause lower oxygen quantities to be incorporated in the μc-Si:H layer that is grown, at the same base pressure.

It was found, within the context of the invention, that the relative degradation-related loss of efficiency of multi-junction solar cells decreases as the absorber layer thickness becomes thinner.

The invention will be explained in more detail below with reference to embodiments and the attached figures.

### FIRST EMBODIMENT

### Production of a μc-Si:H Absorber layer on a Substrate Using Different Deposition Rates

A glass-TCO (Transparent Conductive Oxide) layer system, with a microcrystalline p-layer deposited thereon, was selected as the substrate. The glass has a thickness of approximately 1 millimeter, the TCO layer has a thickness of approximately 500 nanometers, and the p-layer has a thickness of approximately 10 nanometers.

A plasma chamber system was selected, in which the doped p- and n-layers and the undoped absorber layer were deposited in different chambers.

In preparation for the deposition of the μc-Si:H absorber layer on the p-layer, this substrate is first positioned parallel to the showerhead high-frequency electrode with an electrode distance of 10 mm and is heated in a vacuum to a substrate temperature of 200° C. The base pressure is 10⁻⁷ mbar. Thereafter, the plasma chamber, in which substrates measuring up to 30×30 cm² can be coated, is continuously flooded with a hydrogen flow of 4000 sccm (this corresponds to 444.4 sccm per 100 cm² of substrate surface to be coated) and a silane flow of 57 sccm, at a 1 nm/s deposition rate (this corresponds to 6.3 sccm per 100 cm² of substrate surface to be coated), or 102 sccm silane flow, at a 2.5 nm/s deposition rate (this corresponds to 11.3 sccm per 100 cm² of substrate surface to be coated), and the plasma chamber pressure is continuously controlled at 9.3 mbar during the entire deposition process.

The gas mixture present in the chamber is completely discharged from the chamber. This results in the formation of a constant deposition pressure. The process gases are introduced into the plasma chamber through the showerhead high-frequency electrode. If the deposition of the μc-Si:H absorber layer is to take place at a generator power of 800 W, the silane concentration(=silane flow/(sum of silane flow and hydrogen flow)) is adjusted to a value of 1.4%. A silane concentration of 2.5% is set for depositing the μc-Si:H absorber layer at a generator power of 1800 W.

Using the generator, a plasma is ignited between the substrate and the showerhead high-frequency electrode and subsequently controlled to a specific generator power. The plasma excitation frequency is 40.68 MHz. If a deposition rate of 1 nm/s is to be achieved for the μc-Si:H absorber layer, the generator power must be adjusted to a value of 800 W (corresponds to 0.6 W/cm² electrode surface). To achieve a μc-Si:H deposition rate of 2.5 nm/s, a generator power of 1800 W (corresponds to 1.3 W/cm² electrode surface) must be set.

During the deposition of the μc-Si:H absorber layer, all indicated process parameters remain unchanged. The required deposition time is derived from the desired μc-Si:H absorber layer thickness and the μc-Si:H deposition rate related to the respective manufacturing process. The μc-Si:H absorber layer deposition ends when the generator is turned off after the deposition time that has been set has expired.

As a result of the silane concentration that has been set (=silane flow/(sum of silane flow and hydrogen flow)), the μc-Si:H absorber layer is deposited close to the μc-Si:H/a-Si:H junction, and therefore optimized with respect to the layer properties.

An n-doped layer was deposited on the μc-Si:H absorber layer produced according to this method, so as to produce a μc-Si:H single solar cell. This n-doped layer has a thickness of approximately 20 nanometers. The back contact was produced from ZnO/Ag (80 nanometers ZnO and 700 nanometers Ag).

Depending on the μc-Si:H absorber layer thickness and the μc-Si:H deposition rate, the cell efficiency for this single cell produced the following values:

| μc-Si:H | | μc-Si:H | | |
|---|---|---|---|---|
| Solar | μc-Si:H Absorber | Deposition | | |
| Cell no. | Layer Thickness | Rate | Cell Efficiency | Back Contact |
| 1 | 1460 nanometers | 1 nm/s | 9.2% | ZnO/Ag |
| 2 | 1400 nanometers | 2.5 nm/s | 7.8% | ZnO/Ag |
| 3 | 530 nanometers | 1 nm/s | 7.4% | ZnO/Ag |
| 4 | 600 nanometers | 2.5 nm/s | 7.3% | ZnO/Ag |

It is apparent that decreasing the layer thickness of the absorber layer to values of approximately 500 to 600 nanometers (cells 3 to 4) does not result in a reduction in the cell efficiency because of an increase in the deposition rate from 1 nm/s to 2.5 nm/s. In contrast, in the control experiment having an absorber layer thickness according to the prior art (standard: 1000 to 2000 nanometers for single cells; 1000 to 3000 nanometers for multi-junction solar cells), a considerable loss in cell efficiency, from 9.2 to 7.8%, can be measured, due to the increased layer thickness. Consequently, the method according to the invention leads to a considerable increase in the output of solar cells without otherwise unchanged efficiency.

### SECOND EMBODIMENT

### Production of a μc-Si:H Absorber Layer on a Substrate, Additionally Using High Base Pressure

A glass-TCO (Transparent Conductive Oxide) layer system, with a microcrystalline p-layer deposited thereon, was selected as the substrate. The glass has a thickness of approximately 1 millimeter, the TCO layer has a thickness of approximately 500 nanometers, and the p-layer has a thickness of approximately 10 nanometers.

A plasma chamber system was selected, in which the doped p- and n-layers and the undoped absorber layer were deposited in different chambers.

In the evacuated state, the plasma chamber has a base pressure of approximately 10⁻⁸ mbar. To deliberately increase the oxygen content in μc-Si:H absorber layers deposited there, an artificial air leak is provided on the chamber, the intensity of which can be adjusted by way of a needle valve. Depending of how far the needle valve is opened, the base pressure in the plasma chamber increases. The base pressure acts as a measure of the intensity of the air leak and thus of the incorporated oxygen quantity.

In preparation for the deposition of the μc-Si:H absorber layer, the substrate is first positioned parallel to the showerhead high-frequency electrode with an electrode distance of 10 mm and is heated in a vacuum to a substrate temperature of 200° C. Thereafter, the plasma chamber, in which substrates measuring up to 10×10 cm² can be coated, is continuously flooded with a hydrogen flow of 360 sccm and a silane flow of 5.0 sccm (approximately 1.4% silane concentration), with the plasma chamber pressure being controlled to 13.3 mbar.

The gas mixture present in the chamber is completely discharged from the chamber. This again results in the formation of a constant deposition pressure. The process gases are introduced to the process chamber through the showerhead high-frequency electrode.

Using the generator, a plasma between the substrate and the showerhead high-frequency electrode is ignited and then controlled at a generator power of approximately 60 W (corresponds to approximately 0.4 W/cm² electrode surface), whereby a μc-Si:H deposition rate of 0.7 nm/s is achieved. The plasma excitation frequency is 13.56 MHz.

During the deposition of the μc-Si:H absorber layer, all indicated process parameters remain unchanged. The required deposition time is derived from the desired μc-Si:H absorber layer thickness and the μc-Si:H deposition rate related to the manufacturing process. The deposition of the μc-Si:H absorber layer ends when the generator is turned off after the deposition time that has been set has expired.

As a result of the silane concentration that has been set (=silane flow/(sum of silane flow and hydrogen flow)), the μc-Si:H absorber layer is deposited close to the μc-Si:H/a-Si:H junction and therefore optimized with respect to the layer properties.

An n-doped layer was deposited on the μc-Si:H absorber layer produced according to this method, so as to produce a μc-Si:H single solar cell. This n-doped layer has a thickness of approximately 20 nanometers. The back contact was produced from Ag (700 nanometers).

Depending on the base pressure in the plasma chamber adjusted by means of the needle valve and the μc-Si:H absorber layer thickness, the cell efficiency produced the following values:

| μc-Si:H | | | | Cell | |
|---|---|---|---|---|---|
| Solar | μc-Si:H Absorber | Base pressure in | | Effi- | Back |
| Cell no. | Layer Thickness | Plasma Chamber | | ciency | Contact |
| 1 | 520 nanometers | 10⁻⁸ mbar | (no air leak) | 6.1% | Ag |
| 2 | 530 nanometers | 10⁻⁶ mbar | (air leak) | 6.1% | Ag |
| 3 | 400 nanometers | 10⁻⁵ mbar | (air leak) | 4.5% | Ag |
| 4 | 1100 nanometers | 10⁻⁵ mbar | (air leak) | 7.7% | Ag |
| 5 | 1070 nanometers | 10⁻⁶ mbar | (air leak) | 7.2% | Ag |
| 6 | 1020 nanometers | 10⁻⁵ mbar | (air leak) | 5.0% | Ag |
| 7 | 2960 nanometers | 10⁻⁸ mbar | (no air leak) | 7.8% | Ag |
| 8 | 2980 nanometers | 10⁻⁶ mbar | (air leak) | 6.9% | Ag |
| 9 | 3000 nanometers | 10⁻⁵ mbar | (air leak) | 4.1% | Ag |

It is apparent that, with a layer thickness of less than 1000 nanometers for the absorber layer (examples 1-3), even a considerable increase in the base pressure to approximately 10⁻⁵ mbar results in acceptable efficiency losses of only 1.6%. Here, consideration must also be given to the fact that, in example 3, the thickness of the absorber layer is more than 100 nanometers less than in example 1 and example 2, which at this absorber layer thickness level is the cause of the loss of efficiency of 1.6%.

In contrast, above a layer thickness of 1000 nanometers for the absorber layer, considerably increased losses of efficiency can already be detected when increasing the base pressure from 10⁻⁸ to 10⁻⁵ mbar. These losses are already 2.7%.

If the absorber layer thickness is as much as approximately 3000 nanometers, the detectable loss of efficiency is even higher. In this case, it is as much as 3.7% with an increase in the base pressure from 10⁻⁸ to 10⁻⁵ mbar.

These results demonstrate that, even with a slightly elevated deposition rate of 0.7 nm/s over the prior art, and with thin layer thickness of 400 to 530 nanometers for the deposited microcrystalline absorber layer, in the examples here, an additional effect took place. Despite a comparatively very high base pressure of 10⁻⁵ mbar, only a small loss of efficiency was detected. This is absolutely acceptable from a process-related point of view. The loss of efficiency is thus considerably lower than with the thick absorber layers of examples 7 to 9.

With an absorber layer of 530 nanometers, which is comparatively thick in relation to the first embodiment, and a back contact made of ZnO/AG, Example 3 in Table 2 exhibits a corresponding efficiency of approximately 7%.

### THIRD EMBODIMENT

### Production of a μc-Si:H Absorber Layer for a Tandem Solar Cell on a Substrate

In multi-junction solar cells based on amorphous (a-Si:H) and microcrystalline (μc-Si:H) silicon, the overall thickness of the active layers is primarily influenced by the thickness of the μc-Si:H absorber layers. An example of a-Si:H/μc-Si:H-based multi-junction solar cells is a-Si:H/μc-Si:H tandem solar cells, which are composed of exactly one a-Si:H top cell and one μc-Si:H bottom cell. The top cell denotes the cell in which the light enters first.

According to the prior art, the μc-Si:H absorber layer contributes approximately 75% to the overall thickness of the active layer of an a-Si:H/μc-Si:H tandem solar cell.

Because the μc-Si:H bottom absorber layer having a thickness of 1000 to 3000 nanometers has by far the highest single layer'thickness in an a-Si:H/μc-Si:H tandem solar cell, the deposition rate thereof therefore decisively determines the output that a production system can achieve annually.

To produce a solar cell having a p-i-n-p-i-n design for a tandem configuration, a glass-TCO-a-Si:H (Transparent Conductive Oxide) top cell layer system, with a microcrystalline p-layer deposited thereon, is selected as the substrate. The glass has a thickness of approximately 1 millimeter, the TCO layer has a thickness of approximately 500 nanometers, the a-Si:H top cell has a respectively adjusted thickness of approximately 140 to 390 nanometers because of the series connection to the μc-Si:H bottom cell. This means that, depending on the μc-Si:H absorber layer thickness, the absorber layer thickness of the a-Si:H top cell was adjusted so that both single cells supply the same current.

The microcrystalline p-layer deposited thereon has a thickness of approximately 10 nanometers.

In preparation for the deposition of the μc-Si:H absorber layer, the substrate is first positioned parallel to the showerhead high-frequency electrode with an electrode distance of 10 mm and is heated in a vacuum to a substrate temperature of 200° C. The base pressure is approximately 10⁻⁷ mbar. Thereafter, the plasma chamber, in which substrates measuring up to 30×30 cm² can be coated, is continuously flooded with a hydrogen flow of 2700 sccm and a silane flow of 24 sccm (approximately 0.9% silane concentration), with the plasma chamber pressure being controlled to 13.3 mbar.

The gas mixture present in the chamber is completely discharged from the chamber. This again results in the formation of a constant deposition pressure. The process gases are introduced into the process chamber through the showerhead high-frequency electrode.

Using the generator, a plasma between the substrate and the showerhead high-frequency electrode is ignited and then controlled to a generator power of approximately 500 W (corresponds to approximately 0.4 W/cm² electrode surface), whereby a μc-Si:H deposition rate of 0.7 nm/s is achieved. The plasma excitation frequency is 13.56 MHz.

During the deposition of the μc-Si:H absorber layer, all indicated process parameters remain unchanged.

The required deposition time is derived from the desired μc-Si:H absorber layer thickness and the μc-Si:H deposition rate related to the respective manufacturing process. The μc-Si:H absorber layer deposition ends when the generator is turned off, after the set deposition time has expired.

As a result of the adjusted silane concentration (=silane flow/(sum of silane flow and hydrogen flow)), the μc-Si:H absorber layer is deposited close to the μc-Si:H/a-Si:H junction and therefore optimized with respect to the layer properties.

A microcrystalline n-layer was deposited on the μc-Si:H absorber layer produced according to this method, so as to produce a μc-Si:H tandem solar cell. This n-layer has a thickness of approximately 20 nanometers. The back contact was produced from ZnO/Ag (80 nanometers ZnO and 700 nanometers Ag). The a-Si:H/μc-Si:H tandem solar cell thus comprises a μc-Si:H bottom cell on an a-Si:H top cell.

After the starting cell efficiency was determined, the a-Si:H/μc-Si:H tandem solar cells were subsequently exposed to an irradiation intensity of 100 mW/cm² for 1000 hours at a cell temperature of 50° C. in a degradation experiment, so as to also determine the stabilized cell efficiency. The following values were obtained:

| a-Si:H/ | Absorber | | | Relative | |
|---|---|---|---|---|---|
| μc-Si:H | Layer Thick- | | | Degradation- | |
| Tandem | ness of the | Initial | Stabilized | Related | |
| Solar | μc-Si:H | Cell | Cell | Loss of | Back |
| Cell no. | Bottom Cell | Efficiency | Efficiency | Efficiency | Contact |
| 1 | 1850 nm | 11.9% | 9.7% | 18.5% | ZnO/Ag |
| 2 | 1140 nm | 10.6% | 9.3% | 12.3% | ZnO/Ag |
| 3 | 780 nm | 10.5% | 9.5% | 9.5% | ZnO/Ag |
| 4 | 440 nm | 9.0% | 8.4% | 6.7% | ZnO/Ag |

It is apparent that the relative degradation-related loss of efficiency in cells decreases as the absorber layer thickness becomes thinner. While in Example 1, with a layer thickness of 1850 nanometers, this relative loss is still 18.5%, it is only 6.7% in Example 4, with a layer thickness of 440 nanometers. For tandem solar cells, the light-induced degradation is caused almost exclusively by a degradation of the a-Si:H top solar cell.

The consequence of the results of the embodiments is that the production-cost optimum shifts toward considerably lower overall layer thicknesses of <1000 nanometers with high deposition rates of >0.5 nm/s, and optionally with a high base pressure, with an accordingly high final oxygen concentration in the finished solar cell. The a-Si:H/μc-Si:H tandem solar cell no. 4, for example, has an overall layer thickness, for the active semiconductor layers (p-i-n-p-i-n without front and back contacts), of approximately 640 nanometers.

1. A method for depositing microcrystalline silicon on a substrate in a plasma chamber system, comprising the following steps:
prior to initiating the plasma, providing the plasma chamber system with a reactive, silicon-containing gas and hydrogen, or exclusively hydrogen,
initiating the plasma,
after the plasma is initiated, continuously supplying exclusively reactive, silicon-containing gas to the chamber system or, after the plasma is initiated, continuously supplying a mixture comprising a reactive, silicon-containing gas and hydrogen to the chamber system, wherein the concentration of reactive, silicon-containing gas during supply into the chamber is adjusted to greater than 0.5%,
adjusting the plasma power to between 0.1 and 2.5 W/cm² electrode surface,
selecting a deposition rate of greater than 0.5 nm/s and depositing the microcrystalline layer having a thickness of less than 1000 nanometers on the substrate, and
setting a base pressure in the plasma chamber system of at least 10⁻⁶ mbar, and more particularly at least 10⁻⁵ mbar.

2. The method according to claim 1, wherein the flows of the gases, or gas mixtures, supplied to the chamber and discharged from the chamber are controlled so that a constant deposition pressure develops during the method.

3. A method according claim 1, wherein a deposition rate of up to 5.0 nm/s is selected.

4. A method according claim 1, wherein a microcrystalline layer having a thickness of 200 to 800 nm is deposited.

5. A method according to claim 1, wherein an excitation frequency of 13.56 to approximately 100 MHz at an electrode distance of 5 to 25 millimeters is selected.

6. A method according claim 1, wherein the deposition pressure in the plasma chamber is adjusted to between 1 and 25 mbar.

7. A method according claim 1, wherein, after the plasma is initiated, the chamber is continuously supplied exclusively with reactive, silicon-containing gas in a volume flow of 0.5 sccm to 20 sccm/100 cm² coating surface.

8. (canceled)

9. A method according claim 1, wherein a substrate temperature between 100 and 350° C. is selected.

10. A method according to claim 1, wherein the gas mixture present in the chamber is simultaneously discharged at least partially from the chamber.

11. A method according to claim 1, wherein an electrical contact layer and a microcrystalline n-layer deposited thereon, or a glass-TCO-a:Si:H cell comprising a microcrystalline p-layer deposited thereon, or a metal-TCO-a-Si:H cell comprising a microcrystalline p-layer deposited thereon, is selected as the substrate.

12. A solar cell having at least one p-i-n structure, or at least one n-i-p structure, produced according to claim 1.

13. The solar cell according to claim 12, wherein the microcrystalline absorber layer has an oxygen content of more than 2*10¹⁹ to approximately 1*10²¹ oxygen atoms/cm³.

14. The solar cell according to claim 12, wherein the single solar cell has an efficiency of at least 7 to 8%.

15. A solar cell according to claim 1, wherein the solar cell is an a-Si:H/μc-Si:H-based multi-junction solar cell.

16. The solar cell according to claim 1, wherein an overall layer thickness, of all the active semiconductor layers, is less than 1000 nanometers.

17. A method according to claim 1, wherein a deposition rate of between 1.0 and 2.5 nm/s is selected.

18. A method according to claim 1, wherein a microcrystalline layer having a thickness of 400 to 600 nm is deposited.

19. A method according to claim 1, wherein an excitation frequency of 13.56 to approximately 100 MHz at an electrode distance of 10 to 25 millimeters is selected.

20. A method according to claim 1 wherein, after the plasma is initiated, the chamber is continuously supplied exclusively with reactive, silicon-containing gas in a volume flow of 0.5 sccm to 10 sccm/100 cm² coating surface.

21. The solar cell according to claim 12, wherein the single solar cell has an efficiency of at least 7 to 8%.
